(19) United States
(12) Patent Application Publication
(10) Pub. No.: US 2025/0048664 A1
(43) Pub. Date: Feb. 6, 2025

(54) METHOD OF CONTROLLING CHANNEL LENGTH OF SIC MOSFET

(71) Applicant: POWER CUBESEMI INC., Seongnam-si (KR)

(72) Inventors: Tai Young KANG, Gwangju-si (KR); Sin Su KYOUNG, Hanam-si (KR); Tae Jin NAM, Seongnam-si (KR)

(73) Assignee: POWER CUBESEMI INC., Seongnam-si (KR)

(21) Appl. No.: 18/793,436

(22) Filed: Aug. 2, 2024

(30) Foreign Application Priority Data
Aug. 3, 2023 (KR) 10-2023-0101539

(51) Int. Cl. H01L 29/66; H01L 21/04; H01L 29/16

(52) U.S. Cl. CPC H01L 29/66068; H01L 21/0465; H01L 29/1608

(57) ABSTRACT

A method for adjusting a channel length of silicon carbide MOSFET includes depositing a buffer layer and a poly-silicon layer on a first conductivity type epitaxial layer having a plurality of second conductivity type bases, etching the poly-silicon layer to form a poly-silicon pattern, depositing a spacer layer on the poly-silicon pattern and exposed buffer layer to a first deposition thickness, forming a first width of spacers of the poly-silicon pattern by dry etching the spacer layer, forming a pair of first conductivity type source regions on the second conductivity type bases by ion implantation into a first pattern mask formed on the buffer layer, forming a second conductivity type source region on the second conductivity type bases by implanting ions into a second pattern mask, and forming a gate electrode on a first channel extending from the first conductivity type source region to the first conductivity type epitaxial layer.

### CROSS-REFERENCE TO RELATED APPLICATION

The present application claims priority under 35 U.S.C. § 119 (a) to Korean application number 10-2023-0101539, filed on Aug. 3, 2023, in the Korean Intellectual Property Office, which is incorporated herein by reference in its entirety.

### BACKGROUND

The present disclosure relates to a power semiconductor.

FIG. 1 shows a cross section of a silicon carbide power semiconductor in which misalignment occurred.

Referring to FIG. 1, it is a cross-sectional view of a planar gate MOSFET with different lengths of channels formed on both sides near the surface of P-base. The channel conducted by the gate is located in the P-base between the N+ source region and a lateral boundary of the P-base. If the lengths of the two channels formed on both sides of the P-base are not uniform, the resistance of each channel varies. As a result, there may be a difference in current density flowing between channels, which may affect device's durability. To solve the misalignment problem, there have been many attempts to apply self-alignment, which is used in silicon-based semiconductor processes, but due to the nature of silicon carbide-based semiconductors, which must be processed at ultra-high temperatures, it is difficult to use the gate electrode as a pattern mask.

### SUMMARY

The present disclosure intends to propose a silicon carbide power semiconductor manufacturing method that can prevent channel length changes due to misalignment.

According to one aspect of the present disclosure, a method for adjusting a channel length of silicon carbide Metal-Oxide-Semiconductor Field-Effect Transistor (MOSFET) includes depositing a buffer layer and a poly-silicon layer on a first conductivity type epitaxial layer having a plurality of second conductivity type bases spaced apart from one another, etching the poly-silicon layer to form a poly-silicon pattern, depositing a spacer layer on the poly-silicon pattern and exposed buffer layer to a first deposition thickness, forming a first width of spacers extending in a lateral direction on either side of the poly-silicon pattern by dry etching the spacer layer, forming a pair of spaced apart first conductivity type source regions on the plurality of second conductivity type bases by ion implantation into a first pattern mask formed on the buffer layer exposed between the spacers, after the first pattern mask removed, forming a second conductivity type source region on the plurality of second conductivity type bases by implanting ions into a second pattern mask exposing the buffer layer between the pair of first conductivity type source regions, and after removing the buffer layer, the spacer, the poly-silicon pattern, and the second pattern mask, forming a gate electrode on a first channel extending from the first conductivity type source region to the first conductivity type epitaxial layer in the lateral direction.

In one embodiment, the poly-silicon pattern extends in the lateral direction to an inside of the plurality of second conductivity type bases, partially exposing the buffer layer formed on the plurality of second conductivity type bases, and covering the first conductivity type epitaxial layer between the plurality of second conductivity type bases.

In one embodiment, a length of the first channel is a sum of an overlap length between the poly-silicon pattern and the plurality of second conductivity type bases and the first width of the spacer.

In one embodiment, a second channel longer than the first channel is formed by depositing the spacer layer with a second deposition thickness thicker than the first deposition thickness, and a third channel shorter than the first channel is formed by depositing the spacer layer with a third deposition thickness thinner than the first deposition thickness.

In one embodiment, the spacer layer is formed of silicon nitride.

According to another aspect of the present disclosure, a method for adjusting a channel length of silicon carbide MOSFET is provided. The method may include forming a plurality of second conductivity type bases from one another on a first conductivity type epitaxial layer by implanting ions using a first pattern mask, depositing a spacer layer to a first deposition thickness on the first pattern mask and the plurality of second conductivity type bases, by dry etching the spacer layer, forming spacers of a first width extending in a lateral direction on both sides of the first pattern mask, and forming a source pattern mask on the plurality of second conductivity type bases exposed between the spacers, forming a pair of first conductive type source regions spaced apart from each other on the plurality of second conductivity type bases by implanting ions using the source pattern mask, after removing the first pattern mask, the spacer, and the source pattern mask, forming a second conductivity type source region on the plurality of second conductivity type bases by implanting ions into a second pattern mask exposing the plurality of second conductivity type bases between the pair of first conductivity type source regions, and after removing the second pattern mask, forming a gate electrode on a first channel extending from the first conductivity type source region to the first conductivity type epitaxial layer in the lateral direction.

In one embodiment, a length of the first channel is the first width of the spacer.

### BRIEF DESCRIPTION OF DRAWINGS

Hereinafter, embodiments of the disclosure will be described with reference to the accompanying drawings. For the purpose of easy understanding of the disclosure, the same elements will be referred to by the same reference signs. Configurations illustrated in the drawings are examples for describing the disclosure, and do not restrict the scope of the disclosure. Particularly, in the drawings, some elements are slightly exaggerated for the purpose of easy understanding of the disclosure. Since the drawings are used to easily understand the disclosure, it should be noted that widths, depths, and the like of elements illustrated in the drawings might change at the time of actual implementation thereof. Meanwhile, throughout the detailed description of the disclosure, the same components are described with reference to the same reference numerals.

FIG. 1 shows a cross section of a silicon carbide power semiconductor in which misalignment occurred;

FIG. 2A, FIG. 2B, FIG. 2C, FIG. 2D, FIG. 2E, FIG. 2F, FIG. 2G, FIG. 2H, FIG. 2I, FIG. 2J, FIG. 2K, FIG. 2L, FIG. 2M, FIG. 2N and FIG. 2O exemplarily illustrate a process of manufacturing a silicon carbide power semiconductor according to one embodiment of the present disclosure;

FIG. 3 exemplarily illustrates channel length adjustment of a silicon carbide power semiconductor according to one embodiment of the present disclosure; and

FIG. 4A, FIG. 4B, FIG. 4C, FIG. 4D, FIG. 4E, FIG. 4F, FIG. 4G and FIG. 4H, exemplarily illustrate a process of manufacturing a silicon carbide power semiconductor according to another embodiment of the present disclosure.

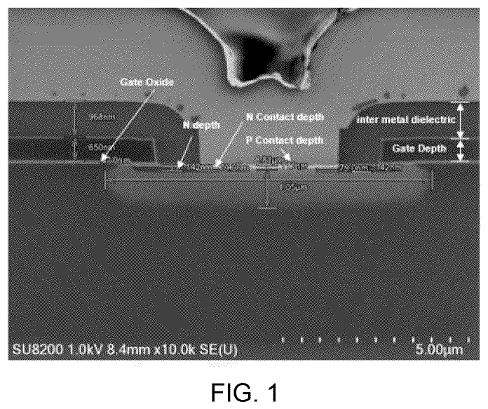

### DETAILED DESCRIPTION

Embodiments which will be described below with reference to the accompanying drawings can be implemented singly or in combination with other embodiments. But this is not intended to limit the present disclosure to a certain embodiment, and it should be understood that all changes, modifications, equivalents or replacements within the spirits and scope of the present disclosure are included. Especially, any of functions, features, and/or embodiments can be implemented independently or jointly with other embodiments. Accordingly, it should be noted that the scope of the disclosure is not limited to the embodiments illustrated in the accompanying drawings.

Terms such as first, second, etc., may be used to refer to various elements, but, these element should not be limited due to these terms. These terms will be used to distinguish one element from another element.

The terms used in the following description are intended to merely describe specific embodiments, but not intended to limit the disclosure. An expression of the singular number includes an expression of the plural number, so long as it is clearly read differently. The terms such as “include” and “have” are intended to indicate that features, numbers, steps, operations, elements, components, or combinations thereof used in the following description exist and it should thus be understood that the possibility of existence or addition of one or more other different features, numbers, steps, operations, elements, components, or combinations thereof is not excluded.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present.

Spatially relative terms, such as “beneath,” “below,” “lower,” “above,” “upper,” and the like, may be used herein for descriptive purposes, and, thereby, to describe one element or feature's relationship to another element(s) or feature(s) as illustrated in the drawings. Spatially relative terms are intended to encompass different orientations of an apparatus in use, operation, and/or manufacture in addition to the orientation depicted in the drawings.

Hereinafter, embodiments of the present disclosure will be described in detail with reference to the accompanying drawings.

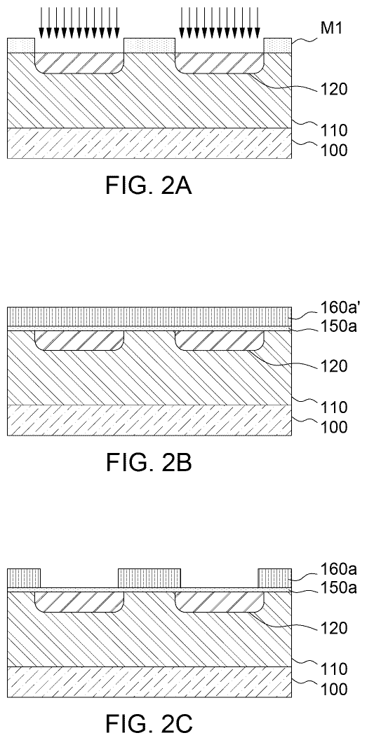

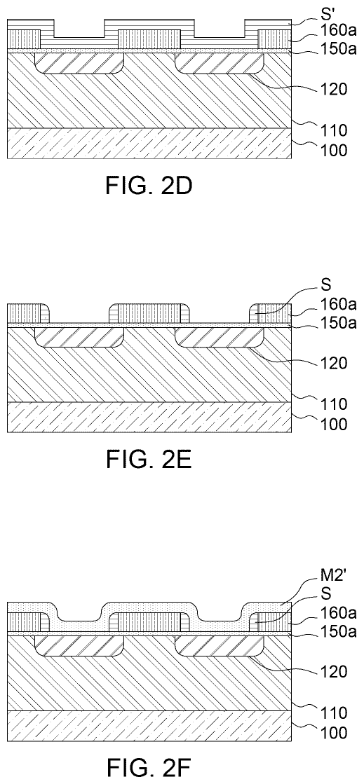

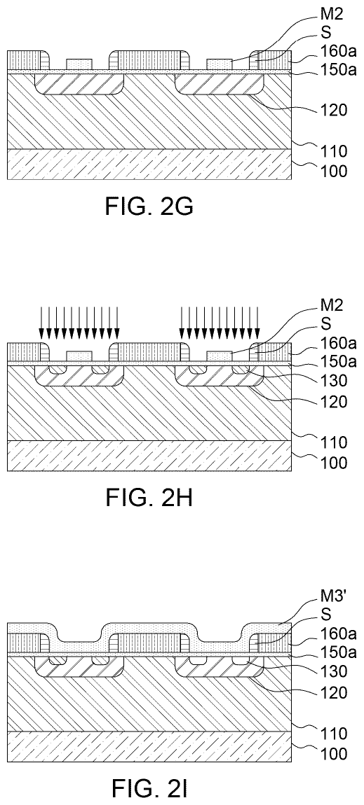

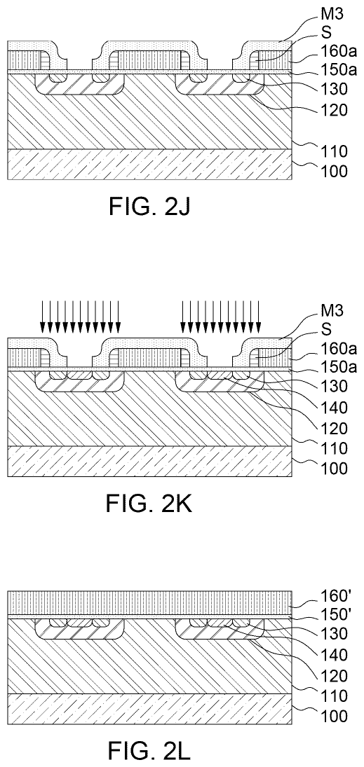

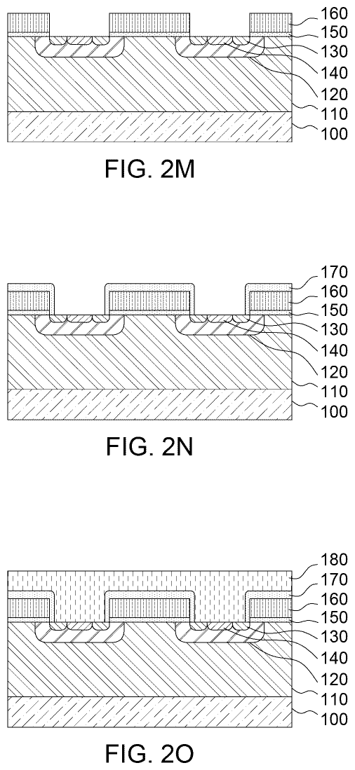

FIG. 2A, FIG. 2B, FIG. 2C, FIG. 2D, FIG. 2E, FIG. 2F, FIG. 2G, FIG. 2H, FIG. 2I, FIG. 2J, FIG. 2K, FIG. 2L, FIG. 2M, FIG. 2N, and FIG. 2O exemplarily illustrate a process of manufacturing a silicon carbide power semiconductor according to embodiment of the present disclosure

FIGS. 2A to 2K show a process for forming a top structure of a silicon carbide power semiconductor, including a second conductivity type base 120, a first conductivity type source region 130 and a second conductivity type source region 140, near a surface of a first conductivity type epitaxial layer 110. The epitaxial layer 110, the base 120 formed in the epitaxial layer 110 and the source regions 130, 140 formed in the base 120 will be referred collectively as a semiconductor layer. On the other hand, FIGS. 2L to 2O are a process of forming a control structure configured for controlling the semiconductor layer, including a gate insulating layer 150, 170, a gate electrode 160, and a source metal 180, on the semiconductor layer.

In FIG. 2A, to form the second conductivity type base 120, a second conductivity type impurity of about 1E16 to about 3E18 may be implanted onto the upper surface of the first conductivity type epitaxial layer 110 using a first pattern mask M1. The first conductivity type substrate 100 is formed of wide band-gap material such as silicon carbide doped with a first conductivity type impurity at a concentration of about 1E18 to about 9E18. The first conductivity type epitaxial layer 110 is a drift region where charges move, and is formed by epitaxially growing the silicon carbide or the like doped with the first conductivity type impurity at a concentration of about 2E15 to about 1E16 from an upper surface of a first conductivity type substrate 100. The first conductivity type may mean an N-type, and the second conductivity type may mean a P-type, but of course, the reverse may also be possible.

In FIG. 2B, after removing the first pattern mask M1, a buffer layer 150a for ion implantation may be deposited on the upper surface of the first conductivity type epitaxial layer 110, and a poly-silicon layer 160a′ for forming a spacer S may be deposited on the buffer layer 150a. The buffer layer 150a may be formed by depositing silicon oxide to a thickness of about 400 Å using PECVD (Plasma Enhanced Chemical Vapor Deposition). The thickness of the poly-silicon layer 160a′ is about 0.5 μm to about 1.0 μm.

In FIG. 2C, the poly-silicon layer 160a′ may be etched to form a poly-silicon pattern 160a. The poly-silicon pattern 160a is formed by removing the poly-silicon layer 160a′ with a photoresist pattern. The photoresist pattern can be formed by removing an top region of the second conductivity type base 120 from a photoresist layer formed on the poly-silicon layer 160a′. The poly-silicon pattern 160a may extend laterally to the inside of the second conductivity type base 120, partially exposing the buffer layer 150a formed on the second conductivity type base 120, and covering the first conductivity type epitaxial layer 110 where the second conductivity type base 120 is not formed. A side of the poly-silicon pattern 160a may be located within a misalignment range set inwardly from a lateral boundary of the second conductivity type base 120, and do not extend beyond the misalignment range. That is, the poly-silicon pattern 160a must extend to the inside of the left and right second conductivity type bases 120 to form channels in the second conductivity type bases 120.

In FIG. 2D, a spacer layer S′ may be deposited on the poly-silicon pattern 160a and the exposed buffer layer 150a. The spacer layer S′ is formed of silicon nitride (Si₃N₄), silicon oxide (SiO₂) or the like. The spacer layer S′ is deposited relatively thicker in the lateral direction from both sides of the poly-silicon pattern 160a than in a vertical direction from an upper surface of the poly-silicon pattern 160a. As a deposition thickness of the spacer layer S′ increases, the relatively thicker region extends in the lateral direction, and the width of the spacer S can be adjusted using the thickness.

In FIG. 2E, a spacer S may be formed by dry etching the spacer layer S′. By etching back and dry etching, the spacer layer S′ formed on the second conductivity type base 120 except for the spacer layer S′ in contact with the poly-silicon pattern 160a is removed. The lateral width of the formed spacer S may be substantially the same.

In FIG. 2F, a silicon oxide layer M2′ may be deposited on the poly-silicon pattern 160a with spacers S formed on both sides and the exposed buffer layer 150a. The silicon oxide layer M2′ may be deposited, for example, by PECVD process.

In FIG. 2G, a second pattern mask M2 for forming the first conductivity type source region 130 may be formed by removing the silicon oxide layer M2′ deposited on the remaining regions except a center region of the second conductivity type base 120.

In FIG. 2H, the first conductivity type source region 130 may be formed by ion implanting a first conductivity type impurity, for example, phosphorus P or nitrogen N. The first conductivity type source region 130 may be formed from the upper surface toward the inside of the second conductivity type base 120 by implanting the first conductivity type impurity of about 1E19 to about 1E20 onto the second conductivity type base 120 through the buffer layer 150a exposed by the spacer S and the second pattern mask M2.

In FIG. 2I, after removing the second pattern mask M2, a silicon oxide layer M3′ may be deposited on the poly-silicon pattern 160a with spacers S formed on both sides and the exposed buffer layer 150a. The silicon oxide layer M2′ may be deposited, for example, by PECVD process.

In FIG. 2J, a third pattern mask M3 for forming the second conductivity type source region 140 may be formed by removing the silicon oxide layer M3′ deposited in the center region of the second conductivity type base 120. The center region is a region between the first conductivity type source regions 130 formed within the same second conductivity type base 120.

In FIG. 2K, the second conductivity type source region 140 may be formed by ion implanting the second conductivity type impurity. The second conductivity type source region 140 may be formed from the upper surface toward the inside of the second conductivity type base 120 by implanting the second conductivity type impurity onto the second conductivity type base 120 between the first conductivity type source regions 130 through the buffer layer 150a exposed by the third pattern mask M3. After the second conductivity type source region 140 is formed, an annealing process may be performed to activate the second conductivity type base 120, the first conductivity type source region 130, and the second conductivity type source region 140.

In FIG. 2L, after removing the buffer layer 150a, the poly-silicon pattern 160a, the spacer S, and third pattern mask M3 from the upper surfaces of the semiconductor layer, a lower insulating layer 150′ may be formed on the semiconductor layer, and a poly-silicon layer 160′ may be deposited on the lower insulating layer 150′. The lower insulating layer 150′ may be formed by a thermal oxidation or by PECVD for depositing silicon oxide.

In FIG. 2M, a gate electrode 160 may be formed by etching the poly-silicon layer 160′. Additionally, a lower insulating layer 150 may be formed by etching the lower insulating layer 150′ on the first conductivity type source regions 130 and the second conductivity type source region 140. The gate electrode 160 may be formed by removing the poly-silicon layer 160′ on the first conductivity type source regions 130 and the second conductivity type source region 140 by using a photoresist pattern formed on the poly-silicon layer 160′. The photoresist pattern can be formed by removing regions on the first conductivity type source region 130 and the second conductivity type source region 140 from a photoresist layer deposited on the poly-silicon layer 160′.

In FIG. 2N, an upper insulating layer 170 may be formed. The upper insulating layer 170 is formed on the side and top surfaces of the gate electrode 160 to electrically insulate the gate electrode 160. The lower insulating layer 150 and the upper insulating layer 170 are collectively referred to as a gate insulating layer.

In FIG. 2O, a source metal layer 180 may be formed to electrically contact the first conductivity type source region 130 and the second conductivity type source region 140.

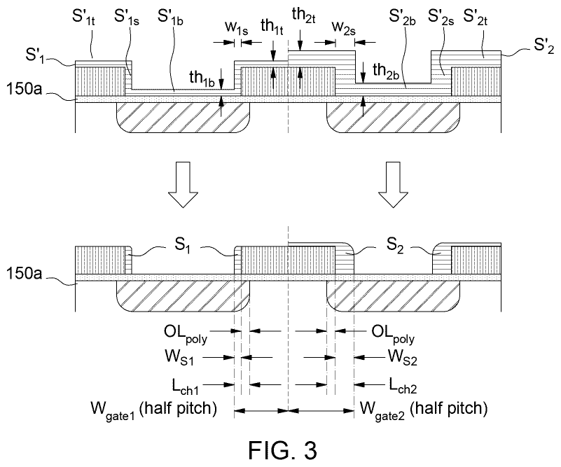

FIG. 3 exemplarily illustrates channel length adjustment of a silicon carbide power semiconductor according to one embodiment of the present disclosure.

Referring to FIG. 3, the channel length can be adjusted by depositing the first spacer layer S1′ and the second spacer layer S2′ at different thicknesses. The second spacer layer S2′ is deposited relatively thicker than the first spacer layer S1′. The thickness refers to the length in the vertical direction, and the width refers to the length in the lateral direction.

The first spacer layer S′₁ includes a first top region S′₁ₜ deposited on the upper surface of the poly-silicon pattern 160a, a first side region S′₁ₛ deposited in the lateral direction on the side of the poly-silicon pattern 160a by a width w₁ₛ and a first bottom region S′_{1b} deposited on the buffer layer 150a and connected at end to the first side region S′₁ₛ. Similarly, the second spacer layer S′₂ includes a second top region S′₂ₜ deposited on the upper surface of the poly-silicon pattern 160a, a second side region S′₂ₛ deposited in the lateral direction on the side of the poly-silicon pattern 160a by a width w₂ₛ and a second bottom region S′_{2b} deposited on the buffer layer 150a and connected at end to the second side region S′₂ₛ. The width was is relatively larger than the width w₁ₛ.

The first side region S′₁ₛ is formed to have the width w₁ₛ relatively greater than the thickness th₁ₜ of the first top region S′₁ₜ and the thickness th_{1b} of the first bottom region S′_{1b}, and the second side region S′₂ₛ is formed to have the width w₂ₛ relatively greater than the thickness th₂ₜ of the second top region S′₂ₜ and the thickness th_{2b} of the second bottom region S′_{2b}. Meanwhile, the thickness th₁ₜ of the first top region S′₁ₜ may be equal to or relatively larger than the thickness th_{1b} of the first bottom region S′_{1b}, and the thickness th₂ₜ of the second top region S′₂ₜ may be equal to or relatively larger than the thickness th_{2b} of the second bottom region S′_{2b}. Therefore, by the same etching process, even if the first bottom region S′_{1b} or the second bottom region S′_{2b} is completely removed to expose the buffer layer 150a, the first side region S′₁ₛ or the second side region S′₂ₛ is partially etched, and the remaining portion that is not etched becomes spacer S₁ or S₂. Accordingly, the width wₛ₁ of the first spacer S₁ may be relatively shorter than the width w₁ₛ of the first side region S′₁ₛ, and the width wₛ₂ of the second spacer S₂ may be relatively shorter than the width w₂ₛ of the second side region S′₂ₛ.

The channel is a passage through which charges flow between the first conductivity type source 130 and the first conductivity type epitaxial layer 110, and is controlled by the gate electrode 160. In detail, the channel is located between the first conductivity type source 130 and the lateral boundary of the second conductivity type base 120 in the surface region of the second conductivity type base 120.

The length of the channel may be determined by an overlap length OL_{poly} between the poly-silicon pattern 160a and the second conductivity type base 120 and the width w_{S} of the spacer S. Although the deposition thicknesses of the first spacer layer S₁′ and the second spacer layer S₂′ are different, the width of the poly-silicon pattern 160a is the same, so the overlap length OL_{poly} between the poly-silicon pattern 160a and the second conductivity type base 120 is substantially identical in both structures illustrated. On the other hand, the width W_{S1} of the first spacer S₁ is relatively shorter than the width W_{S2} of the second spacer S₂. Accordingly, a length L_{ch1} of the first channel illustrated on the left becomes shorter than a length L_{ch2} of the second channel illustrated on the right.

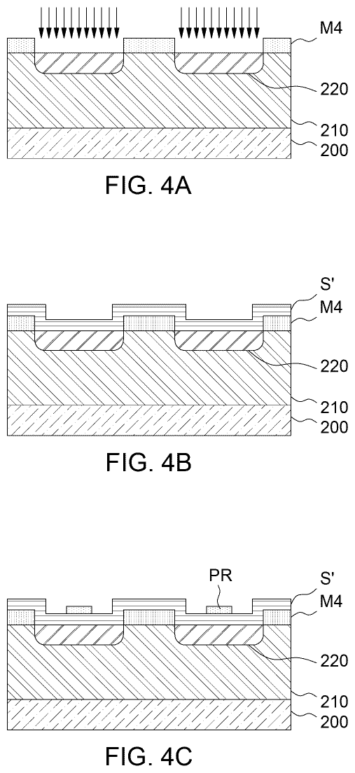

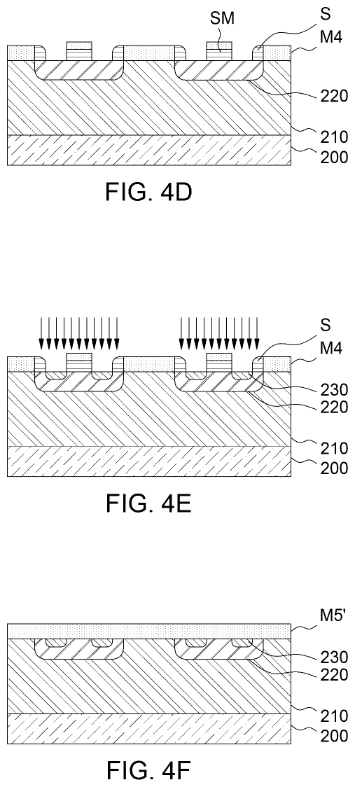

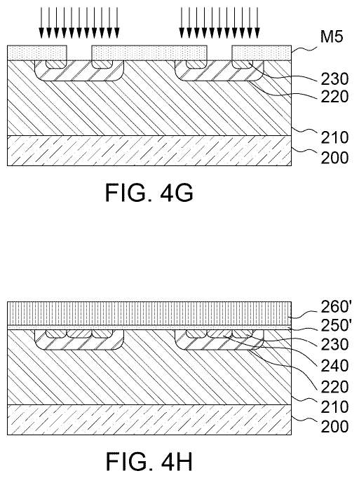

FIG. 4A, FIG. 4B, FIG. 4C, FIG. 4D, FIG. 4E, FIG. 4F, FIG. 4G and FIG. 4H, exemplarily illustrate a process of manufacturing a silicon carbide power semiconductor according to another embodiment of the present disclosure.

FIGS. 4A to 4G show a process for forming a top structure of a silicon carbide power semiconductor, including a second conductivity type base 120, a first conductivity type source region 130 and a second conductivity type source region 140, near a surface of a first conductivity type epitaxial layer 110. Meanwhile, the process of forming a control structure configured for controlling the semiconductor layer, including a gate insulating layer 150, 170, a gate electrode 160, and a source metal 180, on the semiconductor layer is the same as FIGS. 2L to 2O.

In FIG. 4A, to form the second conductivity type base 220, a second conductivity type impurity of about 1E16 to about 3E18 may be implanted onto the upper surface of the first conductivity type epitaxial layer 210 using a fourth pattern mask M4. The fourth pattern mask M4 may be formed by depositing a silicon oxide layer on the first conductivity type epitaxial layer 220 and then removing the silicon oxide layer in the region where the second conductivity type base 220 is to be formed. By the fourth pattern mask M4, the region where the second conductivity type base 220 is to be formed may be exposed. The first conductivity type substrate 200 is formed of wide band-gap material such as silicon carbide doped with a first conductivity type impurity at a concentration of about 1E18 to about 9E18. The first conductivity type epitaxial layer 210 is a drift region where charges move, and is formed by epitaxially growing the silicon carbide or the like doped with the first conductivity type impurity at a concentration of about 2E15 to about 1E16 from an upper surface of a first conductivity type substrate 200.

In FIG. 4B, a spacer layer S′ may be deposited on the fourth pattern mask M4 and the second conductivity type base 220. The spacer layer S′ is formed of silicon nitride (Si₃N₄), silicon oxide (SiO₂) or the like. The spacer layer S′ is deposited relatively thicker in the lateral direction from both sides of the fourth pattern mask M4 than in a vertical direction from an upper surface of the fourth pattern mask M4. As the deposition thickness of the spacer layer S′ increases, the relatively thicker region extends in the lateral direction, and the width of the spacer S can be adjusted using the thickness. The width of the spacer S can determine the length of the channel.

In FIG. 4C, a photoresist pattern PR may be formed on the spacer layer S′ such that it is located in the center region of the second conductive base 220.

In FIG. 4D, a spacer S and a source pattern mask SM may be formed by dry etching the spacer layer S′. By dry etching, the spacer layer S′ formed on top of the second conductivity type base 220 is removed except for the spacer layer S′ in contact with the fourth pattern mask M4 and the spacer layer S′ under the photoresist pattern PR. The width of the formed spacer S in the lateral direction may be substantially the same. The distance between the spacers S from the sides of the source pattern mask SM may be substantially the same.

In FIG. 4E, the first conductivity type source region 230 may be formed by ion implantation of the first conductivity type impurity. The first conductivity type source region 230 may be formed from the upper surface toward the inside of the second conductivity type base 220 by implanting the first conductivity type impurity onto the second conductivity type base 120 exposed by the spacer S and the source pattern mask SM.

In FIG. 4F, after removing the fourth pattern mask M4, the spacer S, and the source pattern mask SM, a silicon oxide layer M5′ may be deposited on the first conductivity type epitaxial layer 210 including the second conductivity type base 220. The silicon oxide layer M2′ may be deposited, for example, by PECVD process.

In FIG. 4G, the second conductivity type source region 240 may be formed by ion implantation of the second conductivity type impurity using the fifth mask pattern M5. The fifth pattern mask M5 for forming the second conductivity type source region 240 is formed by removing the silicon oxide layer M5′ deposited on the center region of the second conductivity type base 220. The center region is the region between the first conductivity type source regions 230 formed within the same second conductivity type base 220.

In FIG. 4H, an annealing process may be performed to activate the second conductivity type base 220, the first conductivity type source region 230, and the second conductivity type source region 240. After the annealing process, the lower insulating layer 250′ and the poly-silicon layer 260′ may be deposited in order on the semiconductor layer.

The above description of the disclosure is exemplary, and those skilled in the art can understand that the disclosure can be modified in other forms without changing the technical concept or the essential feature of the disclosure. Therefore, it should be understood that the above-mentioned embodiments are exemplary in all respects, but are not definitive.

The scope of the disclosure is defined by the appended claims, not by the above detailed description, and it should be construed that all changes or modifications derived from the meanings and scope of the claims and equivalent concepts thereof are included in the scope of the disclosure.

What is claimed is:

1. A method for adjusting a channel length of silicon carbide Metal-Oxide-Semiconductor Field-Effect Transistor (MOSFET), comprising:
depositing a buffer layer and a poly-silicon layer on a first conductivity type epitaxial layer having a plurality of second conductivity type bases spaced apart from one another;
etching the poly-silicon layer to form a poly-silicon pattern;
depositing a spacer layer on the poly-silicon pattern and exposed buffer layer to a first deposition thickness;
forming a first width of spacers extending in a lateral direction on either side of the poly-silicon pattern by dry etching the spacer layer;
forming a pair of spaced apart first conductivity type source regions on the plurality of second conductivity type bases by ion implantation into a first pattern mask formed on the buffer layer exposed between the spacers;
after the first pattern mask removed, forming a second conductivity type source region on the plurality of second conductivity type bases by implanting ions into a second pattern mask exposing the buffer layer between the pair of first conductivity type source regions; and
after removing the buffer layer, the spacer, the poly-silicon pattern, and the second pattern mask, forming a gate electrode on a first channel extending from the first conductivity type source region to the first conductivity type epitaxial layer in the lateral direction.

2. The method of claim 1, wherein the poly-silicon pattern extends in the lateral direction to an inside of the plurality of second conductivity type bases, partially exposing the buffer layer formed on the plurality of second conductivity type bases, and covering the first conductivity type epitaxial layer between the plurality of second conductivity type bases.

3. The method of claim 2, wherein a length of the first channel is a sum of an overlap length between the poly-silicon pattern and the plurality of second conductivity type bases and the first width of the spacer.

4. The method of claim 1, wherein a second channel longer than the first channel is formed by depositing the spacer layer with a second deposition thickness thicker than the first deposition thickness,
wherein a third channel shorter than the first channel is formed by depositing the spacer layer with a third deposition thickness thinner than the first deposition thickness.

5. The method of claim 1, wherein the spacer layer is formed of silicon nitride.

6. A method for adjusting a channel length of silicon carbide MOSFET, comprising:
forming a plurality of second conductivity type bases spaced apart from one another on a first conductivity type epitaxial layer by implanting ions using a first pattern mask;
depositing a spacer layer to a first deposition thickness on the first pattern mask and the plurality of second conductivity type bases;
by dry etching the spacer layer, forming spacers of a first width extending in a lateral direction on both sides of the first pattern mask, and forming a source pattern mask on the plurality of second conductivity type bases exposed between the spacers;
forming a pair of first conductive type source regions spaced apart from each other on the plurality of second conductivity type bases by implanting ions using the source pattern mask;
after removing the first pattern mask, the spacer, and the source pattern mask, forming a second conductivity type source region on the plurality of second conductivity type bases by implanting ions into a second pattern mask exposing the plurality of second conductivity type bases between the pair of first conductivity type source regions; and
after removing the second pattern mask, forming a gate electrode on a first channel extending from the first conductivity type source region to the first conductivity type epitaxial layer in the lateral direction.

7. The method of claim 6, wherein a length of the first channel is the first width of the spacer.

8. The method of claim 6, wherein a second channel longer than the first channel is formed by depositing the spacer layer with a second deposition thickness thicker than the first deposition thickness,
wherein a third channel shorter than the first channel is formed by depositing the spacer layer with a third deposition thickness thinner than the first deposition thickness.
